(19) United States
(12) Patent Application Publication
(10) Pub. No.: US 2014/0374696 A1
(43) Pub. Date: Dec. 25, 2014

(54) LIGHT-EMITTING ELEMENT, DISPLAY PANEL AND MANUFACTURING METHOD THEREOF

(71) Applicants: Yawei Liu, Shenzhen City (CN); Yi-fan Wang, Shenzhen City (CN)

(72) Inventors: Yawei Liu, Shenzhen City (CN); Yi-fan Wang, Shenzhen City (CN)

(73) Assignee: Shenzhen China Star Optoelectronics Technology Co., Ltd., Shenzhen, Guangdong (CN)

(21) Appl. No.: 14/006,311

(22) PCT Filed: Jun. 26, 2013
(86) PCT No.: PCT/CN2013/078048

§ 371 Date: Sep. 19, 2013

(30) Foreign Application Priority Data
Jun. 21, 2013 (CN) 2013102506649

(51) Int. Cl. H01L 27/32; H01L 51/56

(52) U.S. Cl. CPC H01L 27/3244; H01L 51/56
USPC 257/13; 438/35

(57) ABSTRACT

The present invention provides a light-emitting element, display panel and manufacturing method thereof. The light-emitting element includes a cathode and an anode, disposed oppositely; and a light-emitting layer, disposed between the cathode and the anode; the light-emitting layer comprising a mixture of organic material and white-light emitting quantum dot material. As such, the present invention improves the stability and luminance of the light-emitting element, and the light-emitting element has the advantages of ultra-thin, transparent and easy to bend.

### BACKGROUND OF THE INVENTION

1. Field of the Invention

The present invention relates to the field of displaying techniques, and in particular to a light-emitting element, display panel and manufacturing method thereof.

2. The Related Arts

Diode is a semiconductor electronic element and organic light-emitting diode (OLED) is a semiconductor electronic element able to emit light, also called organic electroluminescence display (OELD), OLED possesses the advantages of both CRT and LCD, and is heralded as the panel display and the third-generation display technique of the 21^{st} century, as well as an international research sensation.

The known technical approaches employed to realize the OLED colorization includes the following:
1. RGB light-emitting: this approach is only applicable to organic molecular material easy to sublimate.
2. Starting with blue OLED, and using color conversion method (CCM) to realize other colors.

However, the known light-emitting elements shows poor stability and unsuitable for large-current applications, as well as with a high manufacturing cost. Therefore, it is desirable to devise a light-emitting element with high stability and light-emission efficiency in the context of OLED colorization.

### SUMMARY OF THE INVENTION

The technical issue to be addressed by the present invention is to provide a light-emitting element with higher stability and luminance, as well as providing advantages of ultra-thin, transparent and flexible.

The present invention provides a light-emitting element, which comprises; a cathode and anode, disposed oppositely; a light-emitting layer, disposed between the cathode and the anode; the light-emitting layer comprising a mixture of organic material and white-light emitting quantum dot material, the white-light emitting quantum dot material being white quantum dot material; or a mixture of blue quantum dot material and yellow quantum dot material; or a mixture of red quantum dot material, green quantum dot material and blue quantum dot material; the light-emitting element further comprising an electron transport layer, the electron transport layer being disposed between the light-emitting layer and the cathode; the light-emitting layer further comprising a hole injection layer, at least one layer of the hole injection layer being disposed between the light-emitting layer and the anode.

According to a preferred embodiment of the present invention, the white quantum dot is Group II-VI quantum dot; the blue quantum dot material is at least one of cadmium sulfide, cadmium selenide/zinc sulfide, and silicon nitride; the yellow quantum dot material is at least one of CdSe/CdS/ZnS, ZnS: Mn ions; the red light quantum dot material is CdSe/CdS/ZnS; the green quantum dot material is at least one of CdSe/ZnS, ZnSe: Cu ions; the organic material is any one of 4,4′,4″-tris(carbazole-9-yl)triphenylamine or 2,4,6-tris(carbazole-9-yl)-1,3,5-triazine.

The present invention provides a display panel, which comprises: a plurality of pixel units, with each pixel unit comprising a plurality of sub-pixels, each sub-pixel corresponding to a color, each sub-pixel comprising a substrate and a translucent cover plate, disposed oppositely, and a light-emitting element; the light-emitting element being disposed between the substrate and the translucent cover plate; wherein the light-emitting element comprising: a cathode and anode, disposed oppositely; a light-emitting layer, disposed between the cathode and the anode; the light-emitting layer comprising a mixture of organic material and white-light emitting quantum dot material.

According to a preferred embodiment of the present invention, the white-light emitting quantum dot material is white quantum dot material; or a mixture of blue quantum dot material and yellow quantum dot material; or a mixture of red quantum dot material, green quantum dot material and blue quantum dot material.

According to a preferred embodiment of the present invention, the white quantum dot is Group II-VI quantum dot; the blue quantum dot material is at least one of cadmium sulfide, cadmium selenide/zinc sulfide, and silicon nitride; the yellow quantum dot material is at least one of CdSe/CdS/ZnS, ZnS: Mn ions; the red light quantum dot material is CdSe/CdS/ZnS; the green quantum dot material is at least one of CdSe/ZnS, ZnSe: Cu ions; the organic material is any one of 4,4′,4″-tris(carbazole-9-yl)triphenylamine or 2,4,6-tris(carbazole-9-yl)-1,3,5-triazine.

According to a preferred embodiment of the present invention, the light-emitting element further comprises an electron transport layer; the electron transport layer is disposed between the light-emitting layer and the cathode; the light-emitting layer further comprises a hole injection layer, at least one layer of the hole injection layer is disposed between the light-emitting layer and the anode.

According to a preferred embodiment of the present invention, each sub-pixel comprises a thin-film transistor (TFT) for controlling the light-emitting element corresponding to the sub-pixel to emit light and a corresponding filtering layer; the filtering layer is disposed on the light-emitting surface of the translucent cover plate.

According to a preferred embodiment of the present invention, each pixel unit comprises a first sub-pixel correspondingly displaying red light; a second sub-pixel correspondingly displaying green light; and a third sub-pixel correspondingly displaying blue light; the first sub-pixel, the second sub-pixel and the third sub-pixel comprise respectively a thin-film transistor for controlling the corresponding light-emitting element to emit light.

According to a preferred embodiment of the present invention, each pixel unit comprises a fourth sub-pixel correspondingly displaying white light; and the fourth sub-pixel further comprise respectively a thin-film transistor for controlling the light-emitting element corresponding to the fourth sub-pixel to emit light.

According to a preferred embodiment of the present invention, the first sub-pixel correspondingly displaying red light comprises a red filtering layer; a second sub-pixel correspondingly displaying green light comprises a green filtering layer; and a third sub-pixel correspondingly displaying blue light comprises a blue filtering layer.

The present invention provides a manufacturing method of light-emitting element, which comprises: forming anodes on a glass substrate; forming on the anode in the order of a hole injection layer and a hole transport layer; forming a light-emitting layer comprising a mixture material of organic material and white-light emitting quantum dot material on the hole transport layer; forming an electron transport layer on the light-emitting layer; and forming transparent cathode on the electron transport layer.

According to a preferred embodiment of the present invention, the white-light emitting quantum dot material is white quantum dot material; or a mixture of blue quantum dot material and yellow quantum dot material; or a mixture of red quantum dot material, green quantum dot material and blue quantum dot material; and the step of forming a light-emitting layer comprising a mixture material of organic material and white-light emitting quantum dot material on the hole transport layer comprises: mixing the grains of organic material and white-light emitting quantum dot material with a solvent, coating, and evaporating the solvent to form the light-emitting layer.

According to a preferred embodiment of the present invention, further comprising: packaging the manufactured light-emitting element between a substrate and a translucent cover plate, and forming corresponding filtering layer on the light-emitting surface of the translucent cover plate; and the step of forming anodes on a glass substrate comprising; forming anodes and thin-film transistors connected to the anodes for controlling the light-emitting element corresponding to each sub-pixel to emit light on the glass substrate.

The efficacy of the present invention is that to be distinguished from the state of the art. The material for the light-emitting layer of the light-emitting element of the present invention comprises a mixture of organic material and white-light emitting quantum dot material. Because the quantum dots have advantages of good stability, high efficiency, and long lifespan, the light-emitting element of the present invention shows better stability, high lighting efficiency, and suitable to large-current applications. By increasing the current, the brightness of the light-emitting element can be increased. The use of mixture of organic materials and white-light emitting quantum dots also effectively prevents the quantum dots from agglomeration and oxidation, and avoids fluorescence quenching caused by oxidation. In addition, the use of white-light emitting quantum dots as a luminescent material allows the manufacturing process of the light-emitting element to adopt printing technique so as to reduce the production cost, and is easier to fabricate on a flexible substrate than the known light-emitting elements, such as, LCD, LED. The thickness of the light-emitting layer is only a few hundred nanometers, so that the light-emitting element of the present invention provides the advantages of being ultra-thin, transparent, and easy to bend. Moreover, the color purity of the light-emitting element is high, with 30% to 40% improvement over OLED, and shows better application prospect.

### BRIEF DESCRIPTION OF THE DRAWINGS

To make the technical solution of the embodiments according to the present invention, a brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort. In the drawings:

FIG. 1 is a schematic view showing the structure of a light-emitting element of an embodiment of the present invention;

FIG. 2 is a schematic view showing the structure of a sub-pixel of an embodiment of the display panel of the present invention;

FIG. 3 is a schematic view showing the structure of a pixel unit of an embodiment of the display panel of the present invention;

FIG. 4 is a schematic view showing the structure of a pixel unit of another embodiment of the display panel of the present invention;

FIG. 5 is a schematic view showing the arrangement of a pixel unit of an embodiment of the display panel of the present invention;

FIG. 6 is a schematic view showing the arrangement of a pixel unit of another embodiment of the display panel of the present invention;

FIG. 7 is a schematic view showing the driving circuit of a pixel unit of an embodiment of the display panel of the present invention; and

FIG. 8 is a flowchart showing the manufacturing method of a light-emitting element of the present invention.

### DETAILED DESCRIPTION OF THE PREFERRED EMBODIMENTS

Semiconductor nanocrystals (NCs) refer to the semiconductor nanocrystal dies with the size ranging 1-100 nm. Because the semiconductor nanocrystal is smaller than the exciton Bohr radius of its material, a strong quantum confinement effect is exhibited. The quasi-continuous band evolves into a structure of discrete levels similar to the molecular structure, which shows characteristics of a new material, also known as quantum dots (Quantum Dots, QDs). Because of the external excitation energy (photoluminescence, electroluminescence, cathodoluminescence, etc.), electron transitions from the ground state to the excited state. The excited electrons and holes may form excitons. Electron-hole recombination occurs, and then the final relaxation to the ground state follows. The excess energy released through recombination and relaxation processes, the radiative recombination may send photons. Therefore, the present embodiment utilizes this feature of quantum dot to provide a light-emitting element, with light-emitting layer comprising white-light emitting quantum dot material.

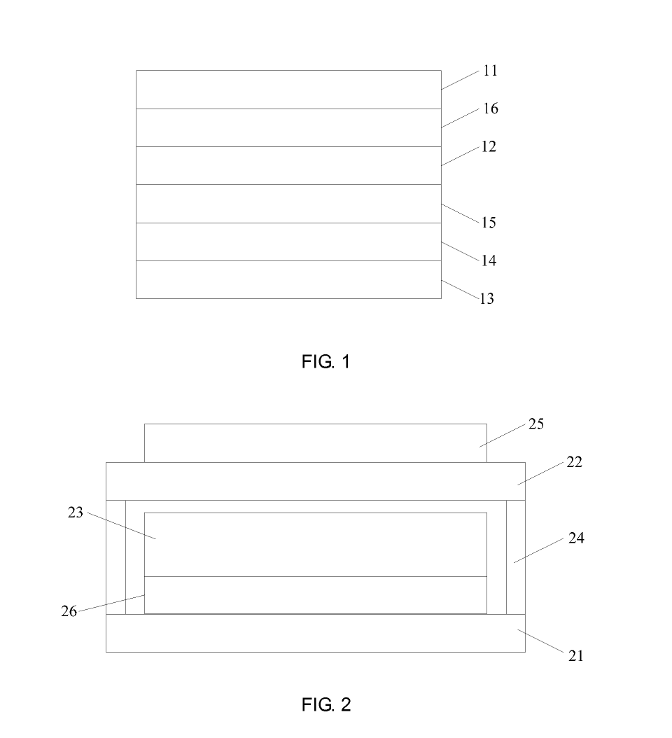

Referring to FIG. 1, FIG. 1 is a schematic view showing the structure of a light-emitting element of an embodiment of the present invention. The light-emitting element of the instant embodiment comprises: a cathode 11 and an anode 13, disposed oppositely; a light-emitting layer 12, disposed between the cathode 11 and the anode 13; the light-emitting layer 12 comprising a mixture of organic material and white-light emitting quantum dot material.

The white-light emitting quantum dot material is white quantum dot material; or a mixture of blue quantum dot material and yellow quantum dot material; or a mixture of red quantum dot material, green quantum dot material and blue quantum dot material.

In the instant embodiment, the white quantum dot is Group II-VI quantum dot; the blue quantum dot material is at least one of cadmium sulfide, cadmium selenide/zinc sulfide, and silicon nitride; the yellow quantum dot material is at least one of CdSe/CdS/ZnS, ZnS: Mn²⁺ ions; the red light quantum dot material is CdSe/CdS/ZnS; the green quantum dot material is at least one of CdSe/ZnS, ZnSe: Cu²⁺ ions.

In the instant embodiment, the organic material is any one of 4,4′, 4″-tris(carbazole-9-yl)triphenylamine (TCTA) or 2,4,6-tris(carbazole-9yl)-1,3,5-triazine(TRZ), wherein the structure of the TCTA material is

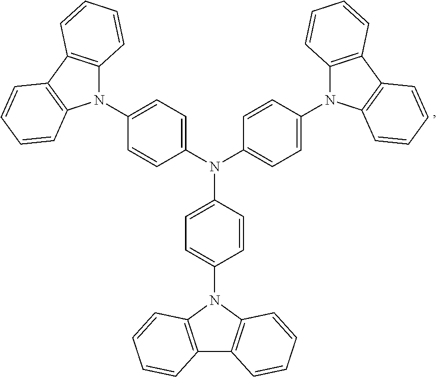 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1]

and the structure of the TRZ material is

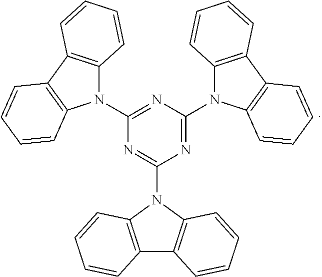 [SMILES: c1ccc2c(c1)c1ccccc1n2-c1nc(-n2c3ccccc3c3ccccc32)nc(-n2c3ccccc3c3ccccc32)n1]

Because quantum dots are nanoparticles, zero-dimensional materials, with high surfactants, and easy to agglomerate, which results in oxidation and causes fluorescence quenching. Through mixing organic materials and white-light emitting quantum dots, the agglomeration and oxidation of the quantum dots can be can effectively prevented.

Of course, in the instant embodiment, the material for light-emitting layer may use a quantum dot material that is capable of emitting white-light by itself. To prevent the agglomeration and oxidation of the quantum dots, when coating the light-emitting layer, a surfactant can be used with white-light emitting quantum dot materials for mixing in a solvent, and then volatile solvent is removed. The surfactant that can be used includes, but not limited to, stearic acid, zinc-based phosphine oxide, polymethyl methacrylate (PMMA) and so on.

Referring to FIG. 1, the light-emitting element of another embodiment of the present invention further comprises a hole injection layer 14, a hole transport layer 15 and an electron transport layer 16, wherein one of the hole injection layer 14 and the hole transport layer 15 may be optional. The hole injection layer 14 and the hole transport layer 15 are disposed between the light-emitting layer 12 and the anode 13. The electron transport layer 16 is disposed between the light-emitting layer and the cathode 11.

In the instant embodiment, the material for the hole injection layer 14 may be polyethylene 3,4-ethylenedioxythiophene thiophene (PEDOT), phthalocyanine blue (CuPc), and so on. The material for hole transport layer 15 may be polyethylene triphenylamine (poly-TPD), N,N′-bis(3-methylphenyl)-1,1′-biphenyl-4,4′diamine (TPD), 4,4′,4″-tris(N,N diphenyl amino)triphenylamine (TDATA), and so on. The material for the electron transport layer 16 may be a fluorescent dye such as 8-hydroxyquinoline aluminum (Alq3), and so on.

The light-emitting element in the instant embodiment may be a quantum dot light-emitting diode (QD-LED). Therefore, the light-emitting element of the present invention provides the following advantages over the organic light-emitting diode (OLED):
(1) The line width of the quantum dot light-emission is between 20-30 nm, which is narrower than the line width of organic light-emission half width (Full Width Half Maximum, FWHM), which is greater than 50 nm. As such, this is a key role for color purity of realistic image;
(2) Quantum dot exhibits better thermal stability than the organic materials. When the light-emitting element is in a high brightness or high current density, the Joule heat is the main reason for degradation of the element. Because of the excellent thermal stability, the light-emitting element based on quantum dot will exhibit long lifespan;
(3) Because the lifespan of the organic materials for the red, green and blue colors is different, the colors of the OLED display change with time. However, with the same kind of material to synthesize quantum dots of different sizes, because of the quantum confinement effect, the light-emission of the three primary colors can be achieved. The same kind of material may exhibit similar degradation of lifespan;
(4) The light-emitting element of the present invention based on the quantum dot can realize the emission of infrared light, and the emission wavelength of the organic material is generally less than 1 micron; and
(5) There is no spin statistics limitation on the quantum dots. The external quantum efficiency (EQE) may reach 100%. The EQE of the QD-LED can be expressed as η_{Ext}=ηr*η_{INT}*η*η_{OUT}; wherein ηr is the probability of electron and hole exciton formation, η_{INT} is the internal quantum efficiency, i.e., the luminescence quantum yield (PLQY), η is the probability of radiative transition, η_{OUT} is external coupling efficiency. The limitation on the organic fluorescent dyes ηr is 25%, wherein the singlet and triplet states formation ratio is 1:3, and only the singlet exciton formation leads to light-emission. However, due to spin-orbit coupling, the ηr of the organic phosphorescent material is greater than 25%. It should be noted that the organic phosphorescent material causes degradation of the parent material. The η_{OUT} of a planar light-emitting element is about 20%, and can be external coupling efficiency can be increased through the micro-cavity structure. For the light-emitting element of the present invention, the η_{INT} can reach 100%, and when the energy levels of the electron and hole are appropriate, the ηr can also reach 100%.

The light-emitting element of the embodiment of the present invention may be organic light-emitting element (i.e.. using mixture of organic material and white-light emitting quantum dot material as material for light-emitting layer), or purely inorganic element (i.e., using pure white-light emitting quantum dot material as material for light-emitting layer). The former can achieve high luminance and be manufactured by flexible process, the latter has higher stability because the material for the other layers of the light-emitting element, such as, hole injection layer, hole transport layer and electron transport layer is all inorganic material.

With the above description, it should be noted that the material for the light-emitting layer of the light-emitting element of the present invention comprises a mixture of organic material and white-light emitting quantum dot material. Because the quantum dots have advantages of good stability, high efficiency, and long lifespan, the light-emitting element of the present invention shows better stability, high lighting efficiency, and suitable to large-current applications. By increasing the current, the brightness of the light-emitting element can be increased. The use of mixture of organic materials and white-light emitting quantum dots also effectively prevents the quantum dots from agglomeration and oxidation, and avoids fluorescence quenching caused by oxidation. In addition, the use of white-light emitting quantum dots as a luminescent material allows the manufacturing process of the light-emitting element to adopt printing technique so as to reduce the production cost, and is easier to fabricate on a flexible substrate than the known light-emitting elements, such as, LCD, LED. The thickness of the light-emitting layer is only a few hundred nanometers, so that the light-emitting element of the present invention provides the advantages of being ultra-thin, transparent, and easy to bend. Moreover, the color purity of the light-emitting element is high, with 30% to 40% improvement over OLED, and shows better application prospect.

Based on the light-emitting element of above embodiment, the present invention further provides a display panel. Referring to FIG. 2, FIG. 2 is a schematic view showing the structure of a sub-pixel of an embodiment of the display panel of the present invention. The display panel of the instant embodiment comprises a plurality of pixel units. Each pixel unit comprises a plurality of sub-pixels, with each sub-pixel corresponding to a color, and each sub-pixel comprises a substrate 21 disposed opposite to a translucent cover plate 22, and a light-emitting element 23, wherein the light-emitting element 23 is disposed between the substrate 21 and the translucent cover plate 22. The substrate 21 and the translucent cover plate 22 are bonded together by a sealant 24 to seal and protect the light-emitting element 23. In the instant embodiment, the composition of each structural layer of the light-emitting element and the corresponding positional relationship is shown in FIG. 1. Refer to FIG. 1 for related description.

In the instant embodiment, the sub-pixel of the present embodiment further comprises a thin-film transistor 26 to control the light-emitting element 23 corresponding to the sub-pixel and corresponding filtering layer 25. The filtering layer 25 is disposed on the light-emitting surface of the translucent cover plate 22 for the white-light emitted from the light-emitting element 23 to be converted to another color through the filtering layer 25. The thin-film transistor 26 is disposed between the substrate 21 and the light-emitting element 23, and connected respectively to the substrate 21 and the anode of the light-emitting element 23.

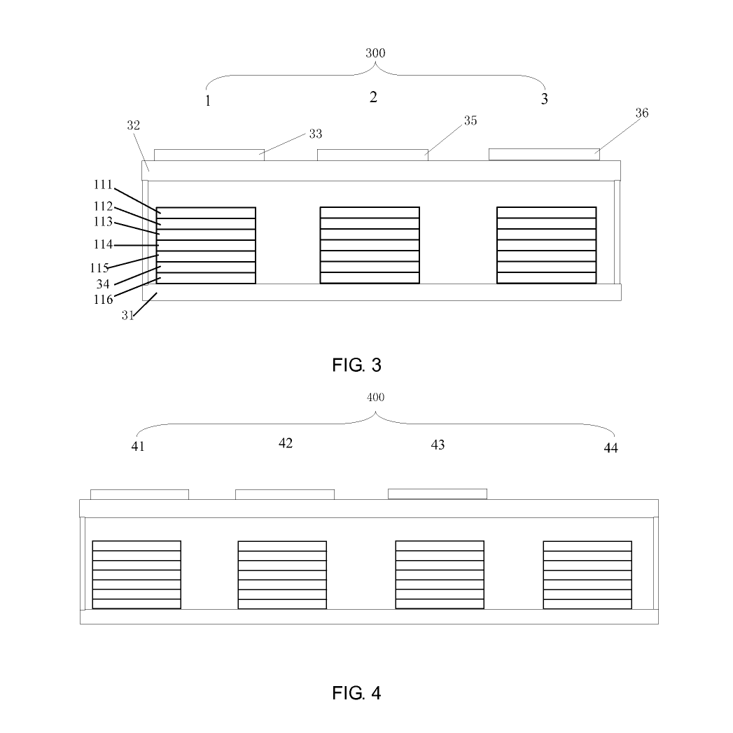

As an exemplar, referring to FIG. 3, FIG. 3 is a schematic view showing the structure of a pixel unit of an embodiment of the display panel of the present invention. In the instant embodiment, the pixel unit 300 may comprise a first sub-pixel 1 correspondingly displaying red light; a second sub-pixel 2 correspondingly displaying green light; and a third sub-pixel 3 correspondingly displaying blue light. Each sub-pixel comprises the substrate 31 and the translucent cover plate 32, disposed oppositely, and a thin-film transistor 34 for controlling the light-emitting element corresponding to the sub-pixel. Each sub-pixel further comprises the light-emitting element packaged between the substrate 31 and the translucent cover plate 32. The light-emitting element comprises the anode 116, the hole injection layer 115, the hole transport layer 114, the light-emitting layer 113, the electron transport layer 112 and transparent cathode 111, respectively (the detailed description of the structure of the light-emitting element is the same as the previous embodiment). The composition of each sub-pixel is similar and is not all labeled in the figure.

In the instant embodiment, the first sub-pixel 1 correspondingly displaying red light comprises a red filtering layer 33 for converting the white light emitted from the light-emitting element to red light; a second sub-pixel 2 correspondingly displaying green light comprises a green filtering layer 35 for converting the white light emitted from the light-emitting element to green light; and a third sub-pixel correspondingly displaying blue light comprises a blue filtering layer 36 for converting the white light emitted from the light-emitting element to blue light.

Referring to FIG. 4, FIG. 4 is a schematic view showing the structure of a pixel unit of another embodiment of the display panel of the present invention. In the instant embodiment, the pixel unit 400 may comprise a first sub-pixel 41 correspondingly displaying red light; a second sub-pixel 42 correspondingly displaying green light; a third sub-pixel 43 correspondingly displaying blue light; and a fourth sub-pixel 44 correspondingly displaying white light. The first sub-pixel 41, second sub-pixel 42 and third sub-pixel 43 have the same structure as in the embodiment of FIG. 3; and the description will not be repeated. The fourth sub-pixel 44 correspondingly displaying white light differs from the first sub-pixel 41, second sub-pixel 42 and third sub-pixel 43 in that the fourth sub-pixel does not comprise a filtering layer. In other words, the white light emitted by the light-emitting element can directly go through to enhance the output of white light and increase the light-emission efficiency of the display panel.

The embodiment of the present invention uses white light +RGB filtering layer to realize the colorization of OLED. This approach greatly simplifies the deposition process because the mature LCD filtering layer technology can be used and requires no mask alignment bit, and thus can lower production costs and can used to manufacture large-size high-resolution OLED. Meanwhile; with the advantages of quantum dot material, the light emission efficiency and stability of the light-emitting element can be further improved.

Of course, the above is only an exemplar of the present invention, In fact, the display panel of the present invention may comprise only any one or two of the above first sub-pixel, second sub-pixel, third sub-pixel and fourth sub-pixel, or even comprises a fifth sub-pixel or more. In addition, the first sub-pixel, second sub-pixel and third sub-pixel are not necessarily corresponding to the red, green or blue colors respectively. Different filtering layers can be used so that the sub-pixels may correspond to other colors.

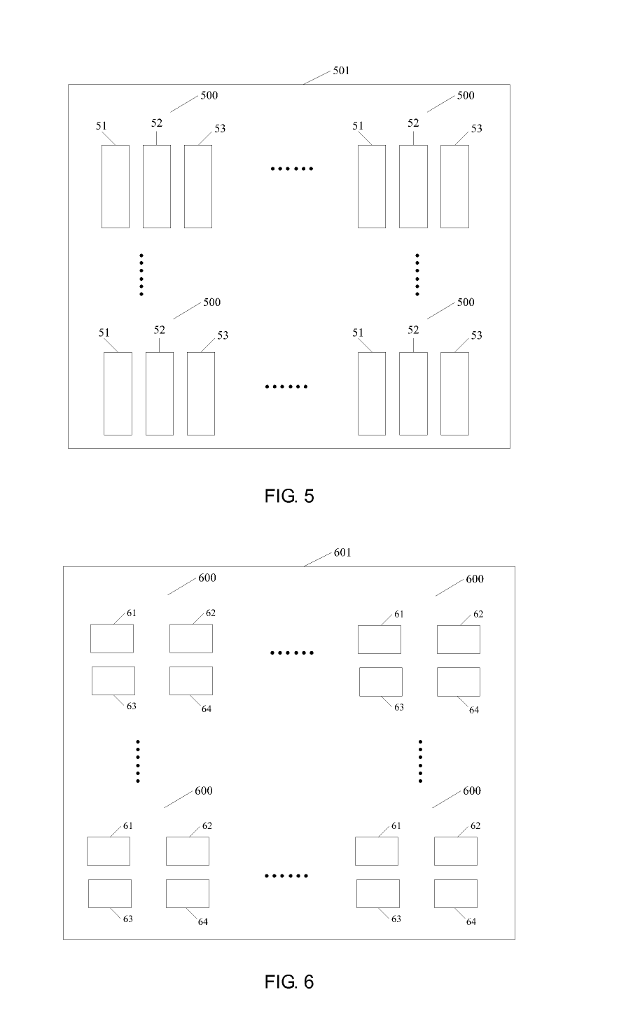

Referring to FIG. 5, FIG. 5 is a schematic view showing the arrangement of a pixel unit of an embodiment of the display panel of the present invention. A display panel 501 comprises a plurality of pixel units 500, and each pixel unit 500 comprises three sub-pixels, namely sub-pixel 51, sub-pixel 52, and the sub-pixel 53. The sub-pixels can be the first sub-pixel, the second sub-pixel and the third sub-pixel described in the above embodiment, or other sub-pixels. The order of the sub-pixels is not fixed and can be adjusted. Moreover, the arrangement of each pixel unit in the present embodiment is only exemplary; and another arrangement may also be adopted.

For multiple sub-pixels, the sub-pixels are not necessarily arranged in a row as the above exemplar. The sub-pixels of a pixel unit can be arranged in multiple rows. Referring to FIG. 6, FIG. 6 is a schematic view showing the arrangement of a pixel unit of another embodiment of the display panel of the present invention. A display panel 601 comprises a plurality of pixel units 600, and each pixel unit 600 comprises four sub-pixels, namely, sub-pixel 61, sub-pixel 62, sub-pixel 63, and sub -pixel 64. The sub-pixels can be the first sub-pixel, the second sub-pixel, the third sub-pixel and the fourth sub-pixel described in the above embodiment, or other sub-pixels. The arrangement of the four sub-pixels can be as in FIG. 6, or in a row as in FIG. 5.

It should be noted that the arrangement of the sub-pixels of the pixel unit is only an exemplar of the embodiment of the present invention. For the pixel unit comprising more sub-pixels, the arrangement can also be in a similar manner as described above; and the present invention will not list all the possible arrangements.

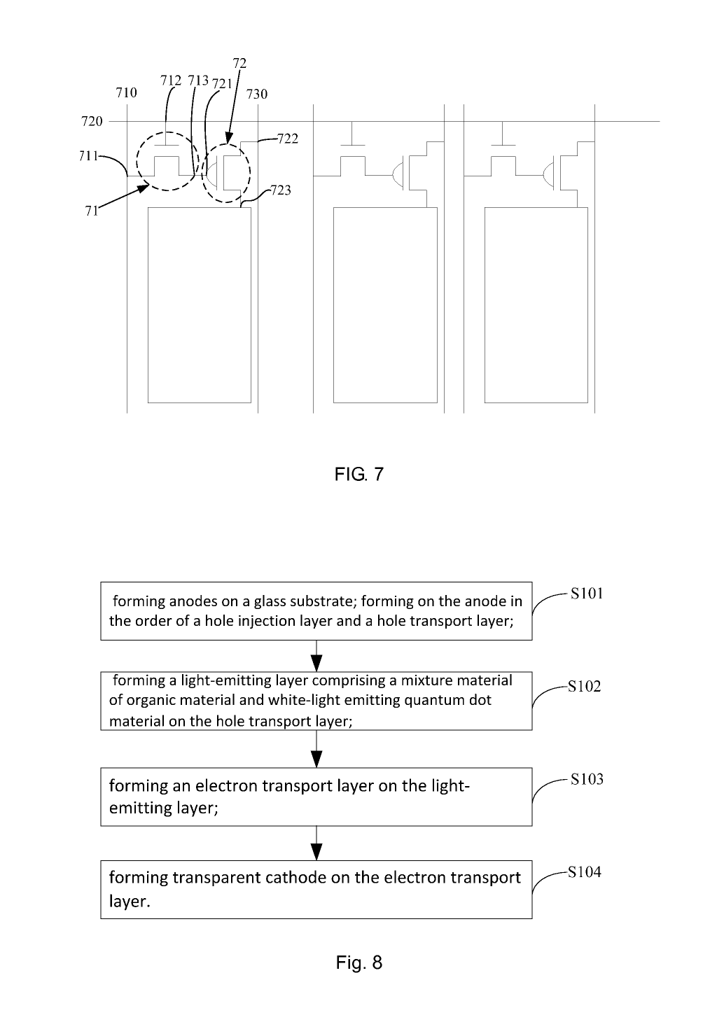

FIG. 7 is a schematic view showing the driving circuit of a pixel unit of an embodiment of the display panel of the present invention. As shown, the pixel unit of the instant embodiment comprises three sub-pixels, namely, the first sub-pixel, the second and the third sub-sub-pixel. Each sub-pixel is driven by two thin-film transistors (TFT), with one as switch TFT and the other as power-supply TFT. The first sub-pixel comprises a first switch TFT and a first power-supply TFT; the second sub-pixel comprises a second switch TFT and a second power-supply TFT; and the third sub-pixel comprises a third switch TFT and a third power-supply TFT. The sub-pixels of each column are connected to the same scan line 720 through respective TFT, and the sub-pixels of each row are connected to the same data line 710 through respective TFT.

The first switch TFT comprises a first source 711, a first gate 712 and a first drain 713, wherein the first source 711 is connected to the data line 710; the first gate 712 is connected to the scan line 720; the first drain 713 is connected to the gate 721 of the first power-supply TFT 72; the source 722 of the first power-supply TFT 72 is connected to the power line 730; the drain 723 of the first power-supply TFT 72 is connected to the anode of the light-emitting element of the first sub-pixel. The power line 730 supplies power to the first sub-pixel through the first power-supply TFT 72 to illuminate the sub-pixel. However, the switch TFT controls whether the power is supplied to the sub-pixel. The data line 710 and the scan line 720 drive the light-emitting element through the first switch TFT 71 and the first power-supply TFT 72 to emit the light so that the first sub-pixel displays the corresponding color, such as, red.

The second switch TFT and the second power-supply TFT, the third switch TFT and the third power-supply TFT are connected correspondingly as the first switch TFT and the first power-supply TFT, as described above, and the description will be omitted.

The data line 710 and the scan line 720 drive the light-emitting element through the second switch TFT and the second power-supply TFT to emit the light so that the second sub-pixel displays the corresponding color, such as, green.

The data line 710 and the scan line 720 drive the light-emitting element through the third switch TFT and the third power-supply TFT to emit the light so that the third sub-pixel displays the corresponding color, such as, blue.

The above driving circuit only illustrates 3 sub-pixels. For a pixel unit comprising more sub-pixels, the connection is similar to the above and the description will be omitted.

In addition, the present invention further provides a display panel, referring to FIG. 3. The display panel comprises a plurality of pixel units 300. Each pixel unit 300 at least comprises two sub-pixels, such as, sub-pixels 1, 3, or sub-pixels 2, 3. Each sub-pixel corresponds to a color, and each sub-pixel comprises a cathode 111, an anode 116 and a light-emitting layer 113. The light-emitting layer 113 is disposed between the cathode 111 and the anode 116. The light-emitting layer 113 comprises the white-light emitting quantum dot material. At least two sub-pixels in each pixel unit comprise a different filtering layer, respectively; for example, the sub-pixel 1 comprises a red filtering layer 33, the sub-pixel 2 comprises a green filtering layer 35; and the sub-pixel 3 comprises a blue filtering layer 36 so that the white light emitted by the light-emitting layer 113 is converted by the filtering layer into another color. As a result, at least two sub-pixels correspond to different colors.

Moreover, preferably, the display panel of the instant embodiment further comprises a sub-pixel, which does not comprise a filtering layer. Referring to FIG. 4, the sub-pixel 44 in FIG. 4 does not comprise a filtering layer (the sub-pixel 44 basically has the same structure as the sub-pixels in FIG. 3, except that sub-pixel 44 does not comprise a filtering layer); therefore, the sub-pixel correspondingly displays white light so as to enhance the white light output and increase the light-emission efficiency of the display panel.

Referring to FIG. 8, FIG. 8 is a flowchart showing the manufacturing method of a light-emitting element of the present invention. The manufacturing method comprises the following steps:

Step S101: forming anodes on a glass substrate; and forming on the anode in the order of a hole injection layer and a hole transport layer.

The formation of a layer of ITO transparent anode on the glass substrate may be accomplished by vapor deposition, coating, and so on. The hole injection layer and the hole transport layer sequentially formed on the transparent anode can be performed according to whether at least one of the hole injecting layer and the hole transport layer, or both layers are to be formed. The instant embodiment forms both the hole injecting layer and the hole injection layer. When forming the hole injection layer and hole transport layer, the hole transport layer is formed away from the anode and on top of the hole injecting anode layer. Deposition or coating may also be used for forming the hole injecting layer and the hole transport layer.

In the instant embodiment, the material for the hole injection layer may be PEDOT, CuPe, and so on and the material for the hole transport layer may be poly-TPD, TPD, TDATA, and so on.

Step S102: forming a light-emitting layer comprising a mixture material of organic material and white-light emitting quantum dot material on the hole transport layer.

The white-light emitting quantum dot material is white quantum dot material; or a mixture of blue quantum dot material and yellow quantum dot material; or a mixture of red quantum dot material, green quantum dot material and blue quantum dot material.

In the instant embodiment, the white quantum dot is Group II-VI quantum dot; the blue quantum dot material is at least one of cadmium sulfide, cadmium selenide/zinc sulfide, and silicon nitride; the yellow quantum dot material is at least one of CdSe/CdS/ZnS, ZnS: Mn²⁺ ions; the red light quantum dot material is CdSe/CdS/ZnS; the green quantum dot material is at least one of CdSe/ZnS, ZnSe: Cu²⁺ ions.

In the instant embodiment, the organic material is any one of 4,4′, 4″-tris(carbazole-9-yl)triphenylamine (TCTA) or 2,4,6-tris(carbazole-9-yl)-1,3,5-triazine (TRZ), wherein the structure of the TCTA material is

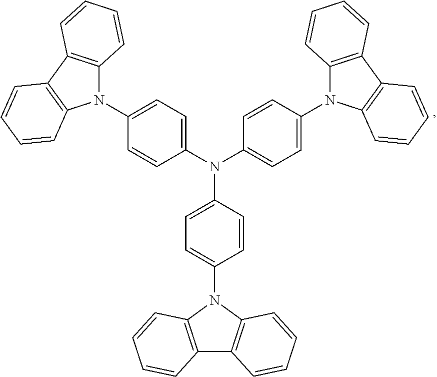 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1]

and the structure of the TRZ material is

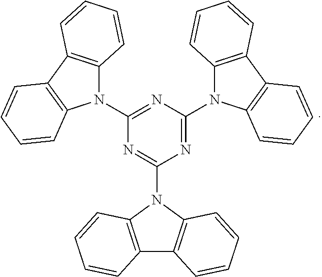 [SMILES: c1ccc2c(c1)c1ccccc1n2-c1nc(-n2c3ccccc3c3ccccc32)nc(-n2c3ccccc3c3ccccc32)n1]

Because quantum dots are nanoparticles, zero-dimensional materials, with high surfactants, and easy to agglomerate, which results in oxidation and causes fluorescence quenching. Through mixing organic materials and white-light emitting quantum dots, the agglomeration and oxidation of the quantum dots can be can effectively prevented.

One of the approaches to forming light-emitting layer in the instant embodiment is to mix the grains of the organic material and white-light emitting quantum dot material with a solvent. Then the mixed solution is coated on the hole transport layer and the volatile solvent evaporates to form the light-emitting layer.

In another embodiment, the material for light-emitting layer may use a quantum dot material that is capable of emitting white-light by itself. To prevent the agglomeration and oxidation of the quantum dots, when coating the light-emitting layer, a surfactant can be used with white-light emitting quantum dot materials for mixing in a solvent, and then volatile solvent is removed to form the light-emitting layer. The surfactant that can be used includes, but not limited to, stearic acid, zinc-based phosphine oxide, polymethyl methacrylate (PMMA) and so on.

Step S103: forming an electron transport layer on the light-emitting layer.

In the step of forming an electron transport layer on the light-emitting layer, the material for the electron transport layer may be fluorescent dye compounds, such as 8-hydroxyquinoline aluminum (Alq3), and so on.

Step S104: forming transparent cathode on the electron transport layer.

In the step of forming transparent cathode on the electron transport layer, the transparent cathode may be formed by deposition or coating process.

Further, when applying the light-emitting element of the present invention to a display panel, the manufacturing method of the present invention further comprises: packaging the manufactured light-emitting element between a substrate and a translucent cover plate, and forming corresponding filtering layer on the light-emitting surface of the translucent cover plate; and the step of forming anodes on a glass substrate comprising forming anodes and thin-film transistors connected to the anodes for controlling the light-emitting element corresponding to each sub-pixel to emit light on the glass substrate.

With the above description, it should be noted that the material for the light-emitting layer of the light-emitting element of the present invention comprises a mixture of organic material and white-light emitting quantum dot material. Because the quantum dots have advantages of good stability, high efficiency, and long lifespan, the light-emitting element of the present invention shows better stability, high lighting efficiency, and suitable to large-current applications. By increasing the current, the brightness of the light-emitting element can be increased. The use of mixture of organic materials and white-light emitting quantum dots also effectively prevents the quantum dots from agglomeration and oxidation, and avoids fluorescence quenching caused by oxidation. In addition, the use of white-light emitting quantum dots as a luminescent material allows the manufacturing process of the light-emitting element to adopt printing technique so as to reduce the production cost, and is easier to fabricate on a flexible substrate than the known light-emitting elements, such as, LCD, LED. The thickness of the light-emitting layer is only a few hundred nanometers, so that the light-emitting element of the present invention provides the advantages of being ultra-thin, transparent, and easy to bend. Moreover, the color purity of the light-emitting element is high, with 30% to 40% improvement over OLED, and shows better application prospect.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the clams of the present invention.

What is claimed is:

1. A light-emitting element, which comprises:
a cathode and an anode, disposed oppositely;
a light-emitting layer, disposed between the cathode and the anode; the light-emitting layer comprising a mixture of organic material and white-light emitting quantum dot material, the white-light emitting quantum dot material being white quantum dot material; or a mixture of blue quantum dot material and yellow quantum dot material; or a mixture of red quantum dot material, green quantum dot material and blue quantum dot material;
the light-emitting element further comprising an electron transport layer, the electron transport layer being disposed between the light-emitting layer and the cathode;
the light-emitting layer further comprising a hole injection layer, at least one layer of the hole injection layer being disposed between the light-emitting layer and the anode.

2. The light-emitting element as claimed in claim 1, wherein
the white quantum dot is Group II-VI quantum dot; the blue quantum dot material is at least one of cadmium sulfide, cadmium selenide/zinc sulfide, and silicon nitride; the yellow quantum dot material is at least one of CdSe/CdS/ZnS, ZnS: Mn ions; the red light quantum dot material is CdSe/CdS/ZnS; the green quantum dot material is at least one of CdSe/ZnS, ZnSe: Cu ions; the organic material is any one of 4,4′, 4″-tris(carbazole-9-yl)triphenylamine or 2,4,6-tris(carbazole-9-yl)-1,3,5-triazine.

3. A display device, which comprises: a plurality of pixel units, with each pixel unit comprising a plurality of sub-pixels, each sub-pixel corresponding to a color, each sub-pixel comprising a substrate and a translucent cover plate, disposed oppositely, and a light-emitting element; the light-emitting element being disposed between the substrate and the translucent cover plate; wherein the light-emitting element comprising:
a cathode and anode, disposed oppositely;
a light-emitting layer, disposed between the cathode and the anode; the light-emitting layer comprising a mixture of organic material and white-light emitting quantum dot material.

4. The display device as claimed in claim 3, wherein:
the white-light emitting quantum dot material is white quantum dot material;
or a mixture of blue quantum dot material and yellow quantum dot material;
or a mixture of red quantum dot material, green quantum dot material and blue quantum dot material.

5. The display device as claimed in claim 4, wherein
the white quantum dot is Group II-VI quantum dot; the blue quantum dot material is at least one of cadmium sulfide, cadmium selenide/zinc sulfide, and silicon nitride; the yellow quantum dot material is at least one of CdSe/CdS/ZnS, ZnS: Mn ions; the red light quantum dot material is CdSe/CdS/ZnS, the green quantum dot material is at least one of CdSe/ZnS, ZnSe: Cu ions; the organic material is any one of 4,4′, 4″-tris(carbazole-9-yl)triphenylamine or 2,4,6-tris(carbazole-9-yl)-1,3,5-triazine.

6. The display device as claimed in claim 3, wherein:
the light-emitting element further comprises an electron transport layer; the electron transport layer is disposed between the light-emitting layer and the cathode;
the light-emitting layer further comprises a hole injection layer, at least one layer of the hole injection layer is disposed between the light-emitting layer and the anode.

7. The display device as claimed in claim 3, wherein:
each sub-pixel comprises a thin-film transistor (TFT) for controlling the light-emitting element corresponding to the sub-pixel to emit light and a corresponding filtering layer; the filtering layer is disposed on the light-emitting surface of the translucent cover plate.

8. The display device as claimed in claim 7, wherein:
each pixel unit comprises a first sub-pixel correspondingly displaying red light; a second sub-pixel correspondingly displaying green light; and a third sub-pixel correspondingly displaying blue light; the first sub-pixel, the second sub-pixel and the third sub-pixel comprise respectively a thin-film transistor for controlling the corresponding light-emitting element to emit light.

9. The display device as claimed in claim 8, wherein:
each pixel unit comprises a fourth sub-pixel correspondingly displaying white light; and the fourth sub-pixel further comprise respectively a thin-film transistor for controlling the light-emitting element corresponding to the fourth sub-pixel to emit light.

10. The display device as claimed in claim 8, wherein:
the first sub-pixel correspondingly displaying red light comprises a red filtering layer; a second sub-pixel correspondingly displaying green light comprises a green filtering layer; and a third sub-pixel correspondingly displaying blue light comprises a blue filtering layer.

11. A manufacturing method of light-emitting element, which comprises:
forming anodes on a glass substrate; forming on the anode in the order of a hole injection layer and a hole transport layer;
forming a light-emitting layer comprising a mixture material of organic material and white-light emitting quantum dot material on the hole transport layer;
forming an electron transport layer on the light-emitting layer; and
forming transparent cathode on the electron transport layer.

12. The manufacturing method as claimed in claim 11, wherein:
the white-light emitting quantum dot material is white quantum dot material;
or a mixture of blue quantum dot material and yellow quantum dot material;
or a mixture of red quantum dot material, green quantum dot material and blue quantum dot material; and
the step of forming a light-emitting layer comprising a mixture material of organic material and white-light emitting quantum dot material on the hole transport layer comprises: mixing the grains of organic material and white-light emitting quantum dot material with a solvent, coating, and evaporating the solvent to form the light-emitting layer.

13. The manufacturing method as claimed in claim 11, further comprising:
packaging the manufactured light-emitting element between a substrate and a translucent cover plate, and forming corresponding filtering layer on the light-emitting surface of the translucent cover plate; and
the step of forming anodes on a glass substrate comprising: forming anodes and thin-film transistors connected to the anodes for controlling the light-emitting element corresponding to each sub-pixel to emit light on the glass substrate.
